(19) United States
(12) Patent Application Publication
(10) Pub. No.: US 2026/0052787 A1
(43) Pub. Date: Feb. 19, 2026

(54) IMAGE SENSING DEVICE

(71) Applicant: MEDIATEK INC., Hsinchu City (TW)

(72) Inventors: Yu-Hsiang KAO, Hsinchu City (TW); Kai-Yu TSENG, Hsinchu City (TW); Chao-Chung CHENG, Hsinchu City (TW); Chi-Cheng JU, Hsinchu City (TW)

(21) Appl. No.: 19/296,027

(22) Filed: Aug. 11, 2025

Related U.S. Application Data
(60) Provisional application No. 63/682,385, filed on Aug. 13, 2024.

(51) Int. Cl. H10F 39/00

(52) U.S. Cl. CPC H10F 39/8053; H10F 39/806

(57) ABSTRACT

An embodiment of the present invention provides an image sensing device. The image sensing device includes a plurality of photoelectric converters, a color filter array, and a plurality of lenses. The color filter array is configured to be arranged on the plurality of photoelectric converters. The plurality of lenses are configured to be arranged on the color filter array. The plurality of lenses comprise a first-type lens and a second-type lens. The second size of the second-type lens is greater than the first size of the first-type lens.

### CROSS REFERENCE TO RELATED APPLICATIONS

This Application claims priority of U.S. Patent Application No. 63/682,385, filed on Aug. 13, 2024, the entirety of which is incorporated by reference herein.

### BACKGROUND OF THE INVENTION

### Field of the Invention

The present invention relates to image sensing devices, and, in particular, it relates to image sensing devices using color filter array (CFA).

### Description of the Related Art

Currently, the image sensors that are available on the consumer market offer good resolution, but they may suffer from poor autofocus performance. As a result, users may experience a noticeable wait time when using these image sensors, leading to a less satisfactory user experience.

Therefore, an image sensor with both high resolution and a high level of autofocus performance is a subject that urgently requires research and development.

### BRIEF SUMMARY OF THE INVENTION

An embodiment of the present invention provides an image sensing device. The image sensing device includes a plurality of photoelectric converters, a color filter array, and a plurality of lenses. The color filter array is configured to be arranged on the plurality of photoelectric converters. The plurality of lenses are configured to be arranged on the color filter array. The plurality of lenses include a first-type lens and a second-type lens. The second size of the second-type lens is greater than the first size of the first-type lens.

In one embodiment, the color filter array includes a first color area; the plurality of lenses include a first lens; wherein the first lens is arranged on the first color area; and the first lens corresponds to the first-type lens.

In one embodiment, the color filter array includes a second color area; the plurality of lenses include a second lens; the second lens is arranged on the second color area; the second lens corresponds to the second-type lens; and the second color area does not overlap the first color area.

In one embodiment, the color filter array includes a third color area; the plurality of lenses include a third lens; the third lens is arranged on the third color area; the third lens corresponds to the second-type lens; and the first color area, the second color area, and the third color area are different from each other.

In one embodiment, the color filter array includes a first color area; the plurality of lenses includes a first lens; the first lens is arranged on the first color area; and the first lens corresponds to the second-type lens.

In one embodiment, the color filter array includes a second color area; the plurality of lenses includes a second lens; the second lens is arranged on the second color area; the second lens corresponds to the first-type lens; and the second color area does not overlap the first color area.

In one embodiment, the color filter array includes a third color area; the plurality of lenses includes a third lens; the third lens is arranged on the third color area; the third lens corresponds to the first-type lens; and the first color area, the second color area, and the third color area are different from each other.

In one embodiment, the color filter array includes Quad Bayer color filter array; the color filter array corresponds to 4×4 cells; the 4×4 cells include a plurality of first color cells, a plurality of second color cells, and a plurality of third color cells.

In one embodiment, the first-type lens corresponds to a 1×1 lens; each one of the plurality of first color cells corresponds to a 1×1 cell; and the first-type lens is arranged on one of the plurality of first color cells.

In one embodiment, the second-type lens includes a first 2×2 lens; each one of the plurality of second color cells corresponds to a 1×1 cell; and the first 2×2 lens is arranged on the plurality of second color cells.

In one embodiment, the second-type lens further includes a second 2×2 lens; each one of the plurality of third color cells corresponds to the 1×1 cell; and the second 2×2 lens is arranged on the plurality of third color cells.

In one embodiment, the second-type lens corresponds to a 2×2 lens; each one of the plurality of first color cells corresponds to a 1×1 cell; and the second-type lens is arranged on the plurality of first color cells.

In one embodiment, the first-type lens includes a first 1×1 lens; each one of the plurality of second color cells corresponds to a 1×1 cell; and the first 1×1 lens is arranged on one of the plurality of second color cells.

In one embodiment, the second-type lens further includes a second 1×1 lens; each one of the plurality of third color cells corresponds to the 1×1 cell; and the second 1×1 lens is arranged on one of the plurality of third color cells.

In one embodiment, the color filter array corresponds to 8×8 cells; the 8×8 cells include a plurality of first color cells, a plurality of second color cells, and a plurality of third color cells.

In one embodiment, the first-type lens corresponds to a 1×1 lens; the second-type lens includes a first 2×2 lens and a second 2×2 lens; each one of the plurality of first color cells, each one of the plurality of second color cells, and each one of the plurality of third color cells corresponds to a 1×1 cell; the first-type lens is arranged on one of the plurality of first color cells; the first 2×2 lens is arranged on four of the plurality of second color cells; and the second 2×2 lens is arranged on four of the plurality of third color cells.

In one embodiment, the first-type lens includes a first 1×1 lens; the second-type lens includes a first 2×2 lens; each one of the plurality of first color cells corresponds to a 1×1 cell; the first 1×1 lens is arranged on one of the plurality of first color cells; and the first 2×2 lens is arranged on four of the plurality of first color cells.

In one embodiment, the second-type lens further includes a second 2×2 lens and a third 2×2 lens; each one of the plurality of second color cells and the plurality of third color cells corresponds to a 1×1 cell; the second 2×2 lens is arranged on four of the plurality of second color cells; the third 233 2 lens is arranged on four of the plurality of third color cells.

In one embodiment, the first-type lens includes a second 1×1 lens and a third 1×1 lens; each one of the plurality of second color cells corresponds to the 1×1 cell; each one of the plurality of third color cells corresponds to the 1×1 cell; the second 1×1 lens is arranged on one of the plurality of second color cells; and the third 1×1 lens is arranged on the one of the plurality of third color cells.

In one embodiment, the second-type lens further includes a second 2×2 lens and a third 2×2 lens; the second 2×2 lens is arranged on four of the plurality of second color cells; and the third 2×2 lens is arranged on four of the plurality of third color cells.

Therefore, according to the technical content of the present disclosure, the image sensing device shown in the embodiment of the present disclosure can achieve the effect of combining high resolution with excellent autofocus performance.

Other features and aspects of the present disclosure will become apparent from the following detailed description of exemplary embodiments with reference to the accompanying drawings.

### BRIEF DESCRIPTION OF THE DRAWINGS

The views of the embodiments of the present disclosure can be better understood through the following detailed description combined with the accompanying drawings. It is worth noting that, according to standard industrial practice, some features may not be drawn to scale. In fact, to facilitate clear description, the dimensions of different features may be increased or decreased, wherein:

FIG. 1 is a block diagram of an image sensing device according to one embodiment of the present disclosure.

FIG. 2A is a top view schematic of an image sensing device according to one embodiment of the present disclosure.

FIG. 2B is a side view schematic of an image sensing device according to one embodiment of the present disclosure.

FIG. 3A is a top view schematic of an image sensing device according to one embodiment of the present disclosure.

FIG. 3B is a side view schematic of an image sensing device according to one embodiment of the present disclosure.

FIG. 4A is a top view schematic of a color filter array according to one embodiment of the present disclosure.

FIG. 4B is a top view schematic of a color filter array according to one embodiment of the present disclosure.

FIG. 5A is a top view schematic of an image sensing device according to one embodiment of the present disclosure.

FIG. 5B is a top view schematic of an image sensing device according to one embodiment of the present disclosure.

FIG. 6 is a top view schematic of an image sensing device according to one embodiment of the present disclosure.

FIG. 7 is a top view schematic of an image sensing device according to one embodiment of the present disclosure.

FIG. 8 is a top view schematic of an image sensing device according to one embodiment of the present disclosure.

### DETAILED DESCRIPTION OF THE INVENTION

To make the description of the present disclosure more detailed and complete, illustrative descriptions are provided below for the implementation aspects and specific embodiments of the present case. However, this is not the sole form of implementing or utilizing the specific embodiments of the present case. The embodiments cover the features of multiple specific embodiments as well as the method steps and their sequence for constructing and operating these specific embodiments. Nevertheless, the same or equivalent functions and sequence of steps can also be achieved using other specific embodiments.

Unless otherwise defined in this specification, the meaning of scientific and technical terms used herein is the same as commonly understood and customary by a person having ordinary skill in the art to which the present case pertains. Furthermore, without conflicting with the context, singular nouns used in this specification cover their plural forms; and plural nouns also cover their singular forms.

In some embodiments of the present disclosure, terms related to joining and connecting, such as “connect,” “interconnect,” and “bond,” unless specifically defined otherwise, may refer to situations where two structures are in direct contact, or may also refer to situations where two structures are not in direct contact, with other structures arranged between these two structures. Moreover, these terms related to connecting and joining may also include cases where both structures are movable, or both structures are fixed. Additionally, “coupled” or “connected” as used herein may refer to two or more components being in direct physical or electrical contact with each other, or indirect physical or electrical contact with each other, and may also refer to two or more components interacting or operating with each other.

Some embodiments of the present disclosure can be understood in conjunction with the drawings, and the drawings of the embodiments of the present disclosure are also considered as part of the description of the embodiments of the present disclosure. It should be understood that the drawings of the embodiments of the present disclosure are not drawn to the actual scale of devices and components. The shapes and thicknesses of the embodiments may be exaggerated in the drawings to clearly illustrate the features of the embodiments of the present disclosure. Furthermore, the structures and devices in the drawings are schematically illustrated to clearly illustrate the features of the embodiments of the present disclosure.

Herein, the term “device” generally refers to an object connected in a certain way to process signals, composed of one or more transistors and/or one or more active/passive components.

Certain terms will be used throughout the entire specification and claims of the present disclosure to refer to specific components. A person having ordinary skill in the art should understand that electronic device manufacturers may refer to the same components by different names. This document is not intended to distinguish between components that have the same function but different names. In the following specification and claims, terms such as “comprising,” “containing,” and “having” are open-ended terms, and therefore they should be interpreted as “containing but not limited to . . . ”. Thus, when the terms “comprising,” “containing,” and/or “having” are used in the description of the present disclosure, they specify the presence of corresponding parts, regions, steps, operations, and/or elements, but do not exclude the presence of one or more corresponding parts, regions, steps, operations, and/or elements.

It should be understood that the components from multiple different embodiments can be substituted, rearranged, and combined to complete other embodiments without departing from the spirit of the present disclosure. Components between various embodiments can be arbitrarily combined and used together, as long as they do not violate the spirit of the invention or conflict with each other.

Unless otherwise defined, all terms used herein (including technical and scientific terms) have the same meaning as commonly understood by a person having ordinary skill in the art to which the present disclosure pertains. It can be understood that these terms, for example, terms defined in commonly used dictionaries, should be interpreted as having a meaning consistent with the relevant art and the background or context of the present disclosure, and should not be interpreted in an idealized or overly formal sense, unless specifically defined in the embodiments of the present disclosure.

In the present disclosure, various directions are not limited to the three axes like the X-axis, Y-axis, and Z-axis of a Cartesian coordinate system, and can be interpreted in a broader sense. For example, the X-axis, Y-axis, and Z-axis may be perpendicular to each other, or may represent different directions that are not perpendicular to each other, but are not limited thereto. For convenience of description, hereinafter, the X-axis direction is the first direction (width direction), the Y-axis direction is the second direction (length direction), and the Z-axis direction is the third direction (thickness or height direction). In some embodiments, the cross-sectional schematic view described herein is a cross-sectional schematic view observed in the XZ plane. In some embodiments, the third direction may be the normal direction of the substrate. In some embodiments, the third direction may be the front direction of the optical sensing device.

In some embodiments, additional components may be added to the image sensing device of the present disclosure. In some embodiments, some components of the image sensing device of the present disclosure may be replaced or omitted. In some embodiments, additional operational steps may be provided before, during, and/or after the manufacturing method of the image sensing device. In some embodiments, some of the described operational steps may be replaced or omitted, and the sequence of some of the described operational steps is interchangeable. Furthermore, it should be understood that some of the described steps may be replaced or deleted for other embodiments of the method. Moreover, in the present disclosure, the number and size of each component in the drawings are for illustrative purposes only, and are not intended to limit the scope of the present disclosure.

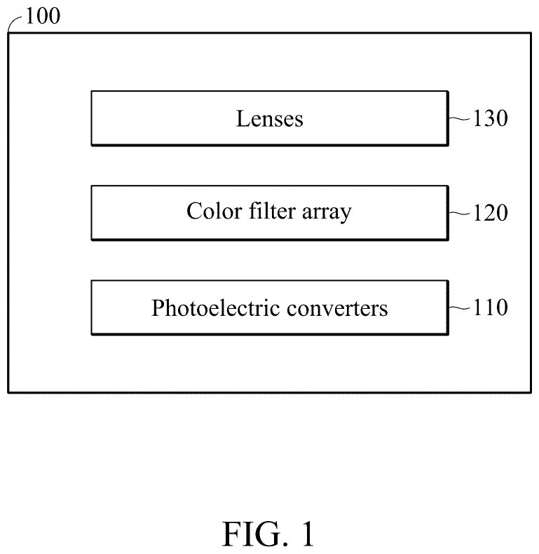

FIG. 1 is a block diagram of an image sensing device according to one embodiment of the present disclosure. As shown in FIG. 1, in one embodiment, an image sensing device 100 includes a plurality of photoelectric converters 110, a color filter array 120, and a plurality of lenses 130.

For example, the image sensing device 100 may include an image sensor. One of the plurality of photoelectric converters 110 may include a photo diode. Each of the plurality of photoelectric converters 110 refers to a single unit of any material, semiconductor, sensor element, or other device that converts incident light into electric current. The color filter array 120 may include any type of color filter array (CFA). One of the plurality of lenses 130 may include an on-chip lens (OCL), but the present disclosure is not limited thereto.

In addition, although the plurality of photoelectric converters 110 and the plurality of lenses 130 are composed of a plurality of elements, for the sake of simplicity in illustration, each of the plurality of photoelectric converters 110 and the plurality of lenses 130 is represented by a single block in the schematic, but the present disclosure is not limited thereto.

In some embodiments, the plurality of lenses 130 are configured in terms of size and position so that incident light from the target scene passes through the color filter array 120, which separates the incident light into different wavelength bands, such as red, green, and blue. The separated light is then received by the photoelectric converters 110, which convert it into electronic signals that can be transmitted to, for example, an image signal processor (ISP) for further signal processing, such as phase detection, image pixel information calculation, denoising, white balance adjustment, color correction, and image enhancement are performed. After these processes, high-quality digital images can be generated for subsequent storage, display, or analysis. In addition, the ISP can also perform advanced functions such as automatic exposure control, face detection, and object tracking according to different application requirements, thereby improving the overall performance of the imaging system and enhancing the user experience.

In some embodiments, the image sensing device 100 may be present (or included) in portable personal computing devices or automotive electronic devices, such as mobile phones, digital cameras, tablet computers, personal digital assistants, or automotive cameras, but the present disclosure is not limited thereto.

Furthermore, the image sensing device 100 may capture in-focus image pixel information and perform phase detection auto focus (PDAF), but the present disclosure is not limited thereto.

In some embodiments, the image sensing device 100 may be a Complementary Metal-Oxide-Semiconductor (CMOS) image sensor or a Charge-Coupled Device (CCD), but the present disclosure is not limited thereto.

In some embodiments, the color filter array 120 act as wavelength-selective pass filters and split incoming light into different color ranges. Although red, blue, and green color filters are commonly used, in other embodiments the color filters can vary according to the color channel requirements of the captured image data, for example including RYB (Red, Yellow, Blue), CYM (Cyan, Yellow, Magenta), ultraviolet, infrared, or near-infrared pass filters.

In one embodiment, the color filter array 120 is configured to be arranged on the plurality of photoelectric converters 110. The plurality of lenses 130 are configured to be arranged on the color filter array 120. The plurality of lenses 130 include a first-type lens and a second-type lens. The second size of the second-type lens is greater than the first size of the first-type lens.

For example, there may be a multiple relationship between the second size and the first size. The first-type lens may have a first diameter, the second-type lens may have a second diameter, and the second diameter may be 1.05, 1.1, 1.5, 2, 2.5, 3, 4 . . . or up to 10 times larger than the first diameter, but the present disclosure is not limited thereto.

In some embodiments, the first-type lens and the second-type lens may be the same type of lens but have different lens diameters, but the present disclosure is not limited thereto. In some embodiments, the first-type lens and the second-type lens may be different types of lenses and have different lens diameters, but the present disclosure is not limited thereto.

In some embodiments, the first-type lens and the second-type lens may be different from each other, but the present disclosure is not limited thereto.

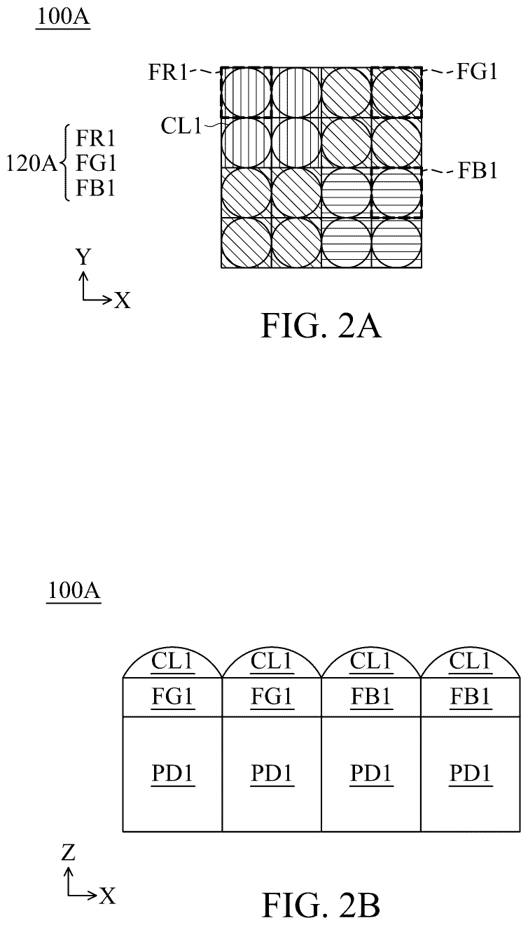

FIG. 2A is a top view schematic of an image sensing device according to one embodiment of the present disclosure. As shown in FIG. 2A, in one embodiment, the image sensing device 100A includes a color filter array 120A and a plurality of lenses CL1. The color filter array 120A may have a plurality of green color filters FG1, a plurality of red color filters FR1, and a plurality of blue color filters FB1.

For example, the image sensing device 100A, the color filter array 120A, and the plurality of lenses CL1 of FIG. 2A may correspond to the image sensing device 100, the color filter array 120, and the plurality of lenses 130 of FIG. 1, but the present disclosure is not limited thereto.

In some embodiments, a basic unit of the image sensing device 100A may have eight green color filters FG1, four red color filters FR1, four blue color filters FB1, and sixteen lenses CL1, but the present disclosure is not limited thereto.

In some embodiments, eight lenses CL1 may be arranged on the eight green color filters FG1, four lenses CL1 may be arranged on the four red color filters FR1, four lenses CL1 may be arranged on four blue color filters FB1, but the present disclosure is not limited thereto.

For example, one lens CL1 may correspond to a 1×1 cell, one green color filter FG1 may correspond to the 1×1 cell, one red color filter FR1 may correspond to the 1×1 cell, and one blue color filter FB1 may correspond to the 1×1 cell, but the present disclosure is not limited thereto.

In some embodiments, the image sensing device 100A or the plurality of lenses CL1 may provide no additional PDAF information, but it is considered to have better image quality.

FIG. 2B is a side view schematic of an image sensing device according to one embodiment of the present disclosure. As shown in FIG. 2B, in one embodiment, FIG. 2B may be the side view of the image sensing device 100A of FIG. 2A. For the sake of brevity, further details will not be repeated here.

It should be specifically noted that the basic unit of the image sensing device 100A may further include a plurality of photoelectric converters PD1. In some embodiments, there may be 16 photoelectric converters PD1, but the present disclosure is not limited thereto.

For example, the plurality of photoelectric converters PD1 of FIG. 2B may correspond to the plurality of photoelectric converters 110 of FIG. 1, but the present disclosure is not limited thereto.

In some embodiments, one photoelectric converter PD1 may correspond to a 1×1 cell, but the present disclosure is not limited thereto. In some embodiments, two lenses CL1 may be arranged on the two green color filters FG1, the two green color filters FG1 may be arranged on two photoelectric converters PD1, but the present disclosure is not limited thereto. In some embodiments, two lenses CL1 may be arranged on two blue color filters FB1, two blue color filters FB1 may be arranged on two photoelectric converters PD1, but the present disclosure is not limited thereto.

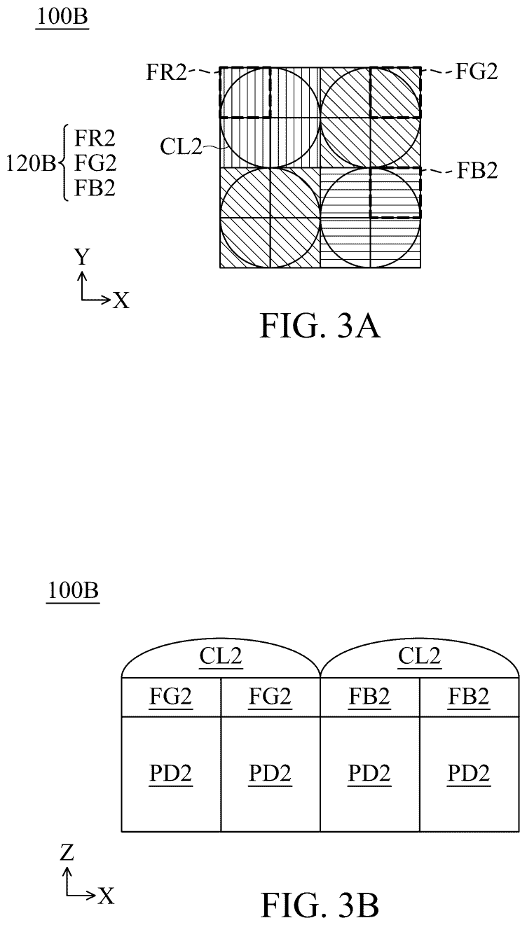

FIG. 3A is a top view schematic of an image sensing device according to one embodiment of the present disclosure. As shown in FIG. 3A, in one embodiment, a basic unit of the image sensing device 100B includes a color filter array 120B and a plurality of lenses CL2. The color filter array 120B may have a plurality of green color filters FG2, a plurality of red color filters FR2, and a plurality of blue color filters FB2.

For example, the image sensing device 100B, the color filter array 120B, and the plurality of lenses CL2 of FIG. 3A may correspond to the image sensing device 100, the color filter array 120, and the plurality of lenses 130 of FIG. 1, but the present disclosure is not limited thereto.

In some embodiments, a basic unit of the image sensing device 100B may have eight green color filters FG2, four red color filters FR2, four blue color filters FB2, and four lenses CL2, but the present disclosure is not limited thereto.

In some embodiments, one lens CL2 may be arranged on the four green color filters FG2, one lens CL2 may be arranged on the four red color filters FR2, one lens CL2 may be arranged on four blue color filters FB2, but the present disclosure is not limited thereto.

For example, one lens CL2 may correspond to a 2×2 cell, one green color filter FG2 may correspond to the 1×1 cell, one red color filter FR2 may correspond to the 1×1 cell, and one blue color filter FB2 may correspond to the 1×1 cell, but the present disclosure is not limited thereto.

In some embodiments, the image sensing device 100B or the plurality of lenses CL2 may be used for improving PDAF performance, but it comes with an image quality degradation. Since one lens CL2 corresponds to a 2×2 cell, the photoelectric converters PD2 below can be used to form multiple pairs, such as two left-right pairs to provide left phase image data and right phase image data, or two top-bottom pairs to provide top phase image data and bottom phase image data. Diagonal pairs can also be used. In some embodiments, a robust phase detection focusing process can use left-right and top-bottom, or left-right, top-bottom, and diagonal phase detection pair data to calculate autofocus. This approach can improve the robustness of the phase detection autofocus process at the edges in all directions.

FIG. 3B is a side view schematic of an image sensing device according to one embodiment of the present disclosure. As shown in FIG. 3B, in one embodiment, FIG. 3B may be the side view of the image sensing device 100B of FIG. 3A. For the sake of brevity, further details will not be repeated here.

It should be specifically noted that the basic unit of the image sensing device 100B may further include a plurality of photoelectric converters PD2. In some embodiments, there may be 16 photoelectric converters PD2 as a basic unit, but the present disclosure is not limited thereto.

For example, the plurality of photoelectric converters PD2 of FIG. 3B may correspond to the plurality of photoelectric converters 110 of FIG. 1, but the present disclosure is not limited thereto.

In some embodiments, one photoelectric converter PD2 may correspond to a 1×1 cell, but the present disclosure is not limited thereto. In some embodiments, one lens CL2 may be arranged on the four green color filters FG2, the four green color filters FG2 may be arranged on four photoelectric converters PD2, but the present disclosure is not limited thereto. In some embodiments, one lens CL2 may be arranged on four blue color filters FB2, four blue color filters FB2 may be arranged on four photoelectric converters PD2, but the present disclosure is not limited thereto.

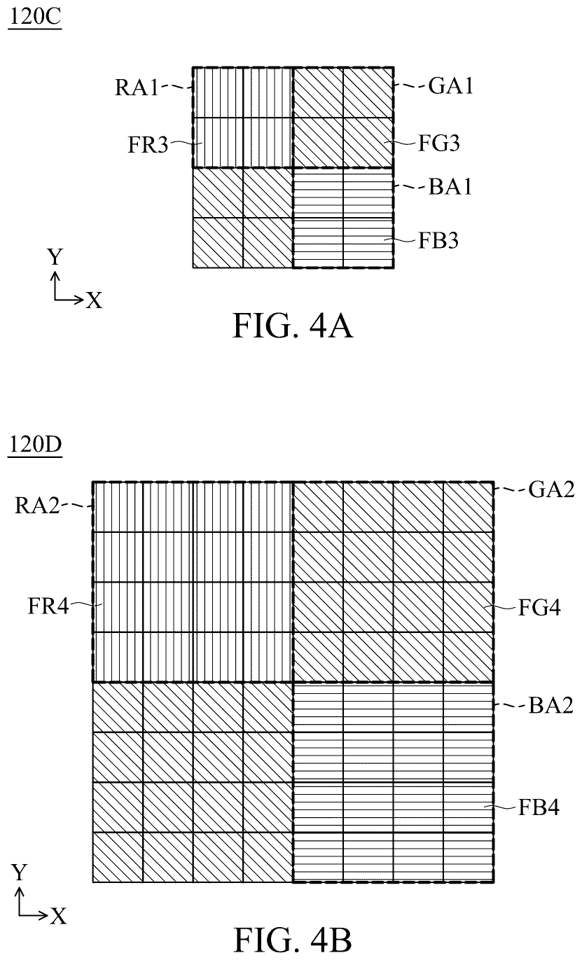

FIG. 4A is a top view schematic of a basic unit of a color filter array according to one embodiment of the present disclosure. As shown in FIG. 4A, in one embodiment, the color filter array 120C includes a plurality of first color areas GA1, a second color area RA1, and a third color area BA1. The first color area GA1 may include a plurality of first color cells FG3. The second color area RA1 may include a plurality of second color cells FR3. The third color area BA1 may include a plurality of third color cells FB3. The term “color cell” refers to a basic unit of a color mosaic or color filter array, but the present disclosure is not limited thereto.

For example, the color filter array 120C of FIG. 4A may correspond to the color filter array 120 of FIG. 1, but the present disclosure is not limited thereto.

In some embodiments, the color filter array 120C, the plurality of first color cells FG3, the plurality of second color cells FR3, and the plurality of third color cells FB3 of FIG. 4A may correspond to the color filter array 120A, the plurality of green color filters FG1, the plurality of red color filters FR1, and the plurality of blue color filters FB1 of FIG. 2A, but the present disclosure is not limited thereto.

In some embodiments, a basic unit of the color filter array 120C may have two first color areas GA1, one second color area RA1, and one third color area BA1, but the present disclosure is not limited thereto. In some embodiments, two first color areas GA1 may have eight first color cells FG3, one second color area RA1 may have four second color cells FR3, and one third color area BA1 may have four third color cells FB3, the color filter array 120C repeatedly uses the basic unit, which may also be referred to as a 4-cell CFA, but the present disclosure is not limited thereto.

In some embodiments, one first color area GA1 may correspond to a 2×2 cell, one second color area RA1 may correspond to a 2×2 cell, and one third color area BA1 may correspond to a 2×2 cell, but the present disclosure is not limited thereto.

In some embodiments, one first color cell FG3 may correspond to a 1×1 cell, one second color cell FR3 may correspond to a 1×1 cell, and one third color cell FB3 may correspond to a 1×1 cell, but the present disclosure is not limited thereto.

FIG. 4B is a top view schematic of a color filter array according to one embodiment of the present disclosure. As shown in FIG. 4B, in one embodiment, the color filter array 120D includes a plurality of first color areas GA2, a second color area RA2, and a third color area BA2. The first color area GA2 may include a plurality of first color cells FG4. The second color area RA2 may include a plurality of second color cells FR4. The third color area BA2 may include a plurality of third color cells FB4.

For example, the color filter array 120D of FIG. 4A may correspond to the color filter array 120 of FIG. 1, but the present disclosure is not limited thereto.

In some embodiments, the color filter array 120D, the plurality of first color cells FG4, the plurality of second color cells FR4, and the plurality of third color cells FB4 of FIG. 4B may correspond to the color filter array 120A, the plurality of green color filters FG1, the plurality of red color filters FR1, and the plurality of blue color filters FB1 of FIG. 2B, but the present disclosure is not limited thereto.

In some embodiments, a basic unit of the color filter array 120D may have two first color areas GA2, one second color area RA2, and one third color area BA2, but the present disclosure is not limited thereto. In some embodiments, two first color areas GA2 may have Thirty-two first color cells FG4, one second color area RA2 may have sixteen second color cells FR4, and one third color area BA2 may have sixteen third color cells FB4, the color filter array 120D repeatedly uses the basic unit, which may also be referred to as a 16-cell CFA, but the present disclosure is not limited thereto.

In some embodiments, one first color area GA2 may correspond to a 4×4 cell, one second color area RA2 may correspond to a 4×4 cell, and one third color area BA2 may correspond to a 4×4 cell, but the present disclosure is not limited thereto.

In some embodiments, one first color cell FG4 may correspond to a 1×1 cell, one second color cell FR4 may correspond to a 1×1 cell, and one third color cell FB4 may correspond to a 1×1 cell, but the present disclosure is not limited thereto.

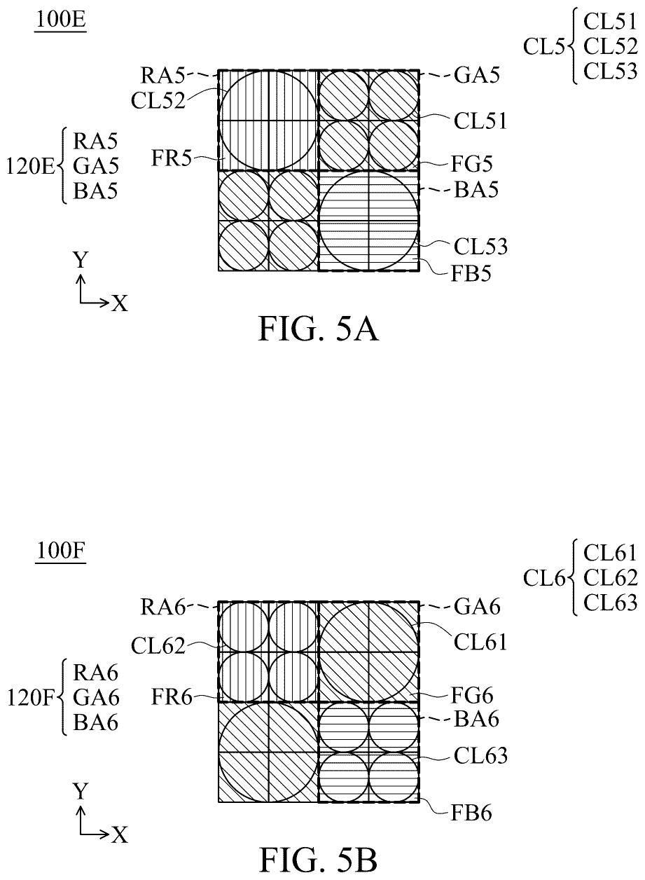

FIG. 5A is a top view schematic of an image sensing device according to one embodiment of the present disclosure. As shown in FIG. 5A, in one embodiment, the image sensing device 100E includes a color filter array 120E and a plurality of lenses CL5. The color filter array 120E may include a plurality of first color areas GA5, a second color area RA5, and a third color area BA5. The first color areas GA5 may include a plurality of first color cells FG5. The second color area RA5 may include a plurality of second color cells FR5. The third color area BA5 may include a plurality of third color cells FB5. The plurality of lenses CL5 may include the first-type lens CL51 and the second-type lens CL52 and CL53.

For example, the image sensing device 100E, the color filter array 120E, and the plurality of lenses CL5 of FIG. 5A may correspond to the image sensing device 100, the color filter array 120, and the plurality of lenses 130 of FIG. 1, but the present disclosure is not limited thereto.

In some embodiments, the color filter array 120E, the plurality of first color cells FG5, the plurality of second color cells FR5, and the plurality of third color cells FB5 of FIG. 5A may correspond to the color filter array 120A, the plurality of green color filters FG1, the plurality of red color filters FR1, and the plurality of blue color filters FB1 of FIG. 2A, but the present disclosure is not limited thereto.

In some embodiments, the first-type lens CL51 of FIG. 5A may correspond to one of the plurality of lenses CL1 of FIG. 2A, and the second-type lens CL52 and CL53 of FIG. 5A may correspond to one of the plurality of lenses CL2 of FIG. 3A, but the present disclosure is not limited thereto.

In some embodiments, the color filter array 120E may have two first color areas GA5, one second color area RA5, and one third color area BA5, but the present disclosure is not limited thereto. In some embodiments, two first color areas GA5 may have eight first color cells FG5, one second color area RA5 may have four second color cells FR5, and one third color area BA5 may have four third color cells FB5, but the present disclosure is not limited thereto.

In some embodiments, each first-type lens CL51 may be arranged on one first color cells FG5, each second-type lens CL52 may be arranged on four second color cells FR5, each second-type lens CL53 may be arranged on four third color cells FB5. In other words, eight first-type lens CL51 may be arranged on the eight first color cells FG5, one second-type lens CL52 may be arranged on four second color cells FR5, one second-type lens CL53 may be arranged on four third color cells FB5, but the present disclosure is not limited thereto.

In some embodiments, one first color area GA5 may correspond to the 2×2 cell, one second color area RA5 may correspond to the 2×2 cell, and one third color area BA5 may correspond to the 2×2 cell, but the present disclosure is not limited thereto.

In some embodiments, one first color cell FG5 may correspond to the 1×1 cell, one second color cell FR5 may correspond to the 1×1 cell, and one third color cell FB5 may correspond to the 1×1 cell, but the present disclosure is not limited thereto.

In some embodiments, one first-type lens CL51 may correspond to the 1×1 cell, the second-type lens CL52 or CL53 may correspond to the 2×2 cell, but the present disclosure is not limited thereto.

In some embodiments, 1×1 OCL may be arranged on green pixel, 2×2 OCL may be arranged on red pixel, 2×2 OCL may be arranged on blue pixel. Therefore, the image sensing device 100E may exhibit improved PDAF performance in the red and blue channels, and better image quality in the green channel, but the present disclosure is not limited thereto.

For example, 1×1 OCL may correspond to the first-type lens CL51, 2×2 OCL may correspond to the second-type lens CL52 or CL53, the green pixel may correspond to the plurality of first color areas GA5, the red pixel may correspond to the second color area RA5, and the blue pixel may correspond to the third color area BA5, but the present disclosure is not limited thereto.

In some embodiments, the image sensing device 100E may have better PDAF performance and better image quality, but the present disclosure is not limited thereto.

Please refer to FIG. 1 and FIG. 5A, in one embodiment, the color filter array 120 and 120E further includes a first color area GA5. The plurality of lenses 130 and CL5 include a first lens CL51. The first lens CL51 is arranged on the first color area GA5. The first lens CL51 corresponds to the first-type lens.

In one embodiment, the color filter array 120 and 120E includes a second color area RA5. The plurality of lenses 130 and CL5 include a second lens CL52. The second lens CL52 is arranged on the second color area RA5. The second lens CL52 corresponds to the second-type lens. The second color area RA5 does not overlap the first color area GA5.

In one embodiment, the color filter array 120 and 120E further includes a third color area FB5. The plurality of lenses includes a third lens CL53. The third lens CL53 is arranged on the third color area FB5.The third lens CL53 corresponds to the second-type lens. The first color area GA5, the second color area RA5, and the third color area BA5 are different from each other.

In one embodiment, the color filter array 120 and 120E includes Quad Bayer color filter array, which may also be referred to as a 4-cell CFA. The color filter array corresponds to 4×4 cells. The 4×4 cells include a plurality of first color cells FG5, a plurality of second color cells FR5, and a plurality of third color cells FB5.

In one embodiment, the first-type lens corresponds to a 1×1 lens CL51. One of the plurality of first color cells FG5 corresponds to a 1×1 cell. The first-type lens is arranged on the one of the plurality of first color cells FG5.

In one embodiment, the second-type lens includes a first 2×2 lens CL52. One of the plurality of second color cells FR5 corresponds to a 1×1 cell. The first 2×2 lens CL5 is arranged on the plurality of second color cells FR5.

In one embodiment, the second-type lens further includes a second 2×2 lens CL53. One of the plurality of third color cells FB5 corresponds to the 1×1 cell. The second 2×2 lens CL53 is arranged on the plurality of third color cells FB5.

FIG. 5B is a top view schematic of an image sensing device according to one embodiment of the present disclosure. As shown in FIG. 5B, in one embodiment, the image sensing device 100F includes a color filter array 120F and a plurality of lenses CL6. The color filter array 120F may include a plurality of first color areas GA6, a second color area RA6, and a third color area BA6. The first color area GA6 may include a plurality of first color cells FG6. The second color area RA6 may include a plurality of second color cells FR6. The third color area BA6 may include a plurality of third color cells FB6. The plurality of lenses CL6 may include the second-type lens CL61 and the first-type lens CL62 and CL63.

For example, the image sensing device 100F, the color filter array 120F, and the plurality of lenses CL6 of FIG. 5B may correspond to the image sensing device 100, the color filter array 120, and the plurality of lenses 130 of FIG. 1, but the present disclosure is not limited thereto.

In some embodiments, the color filter array 120F, the plurality of first color cells FG6, the plurality of second color cells FR6, and the plurality of third color cells FB6 of FIG. 5B may correspond to the color filter array 120A, the plurality of green color filters FG1, the plurality of red color filters FR1, and the plurality of blue color filters FB1 of FIG. 2A, but the present disclosure is not limited thereto.

In some embodiments, the second-type lens CL61 of FIG. 5B may correspond to one of the plurality of lenses CL2 of FIG. 3A, and the first-type lens CL62 and CL63 of FIG. 5B may correspond to one of the plurality of lenses CL1 of FIG. 2A, but the present disclosure is not limited thereto.

In some embodiments, the color filter array 120F may have two first color areas GA6, one second color area RA6, and one third color area BA6, but the present disclosure is not limited thereto. In some embodiments, two first color areas GA6 may have eight first color cells FG6, one second color area RA6 may have four second color cells FR6, and one third color area BA6 may have four third color cells FB6, but the present disclosure is not limited thereto.

In some embodiments, eight second-type lens CL61 may be arranged on the eight first color cells FG6, one first-type lens CL62 may be arranged on four second color cells FR6, one first-type lens CL63 may be arranged on four third color cells FB6, but the present disclosure is not limited thereto.

In some embodiments, one first color area GA6 may correspond to the 2×2 cell, one second color area RA6 may correspond to the 2×2 cell, and one third color area BA6 may correspond to the 2×2 cell, but the present disclosure is not limited thereto.

In some embodiments, one first color cell FG6 may correspond to the 1×1 cell, one second color cell FR6 may correspond to the 1×1 cell, and one third color cell FB6 may correspond to the 1×1 cell, but the present disclosure is not limited thereto.

In some embodiments, one second-type lens CL61 may correspond to the 2×2 cell, the first-type lens CL62 or CL63 may correspond to the 1×1 cell, but the present disclosure is not limited thereto.

In some embodiments, 2×2 OCL may be arranged on green pixel, 1×1 OCL may be arranged on red pixel, 1×1 OCL may be arranged on blue pixel. Therefore, the image sensing device 100F may exhibit improved PDAF performance in the green channel and better image quality in the red and blue channels.

For example, 2×2 OCL may correspond to the second-type lens CL61, 1×1 OCL may correspond to the first-type lens CL62 or CL63, the green pixel may correspond to the plurality of first color areas GA6, the red pixel may correspond to the second color area RA6, and the blue pixel may correspond to the third color area BA6, but the present disclosure is not limited thereto.

In some embodiments, the image sensing device 100F may have better PDAF performance and better image quality, but the present disclosure is not limited thereto.

Please refer to FIG. 1 and FIG. 5B, in one embodiment, the color filter array 120 and 120F includes a first color area GA6. The plurality of lenses 130 and CL6 include a first lens CL61. The first lens CL61 is arranged on the first color area GA6. The first lens CL61 corresponds to the second-type lens.

In one embodiment, the color filter array 120F further includes a second color area RA6. The plurality of lenses further include a second lens CL62. The second lens CL62 is arranged on the second color area RA6. The second lens CL62 corresponds to the first-type lens. The second color area RA6 does not overlap the first color area GA6.

In one embodiment, the color filter array 120F further includes a third color area BA6. The plurality of lenses further include a third lens CL63. The third lens CL63 is arranged on the third color area BA6. The third lens CL63 corresponds to the first-type lens. The first color area GA6, the second color area RA6, and the third color area BA6 are different from each other.

In one embodiment, the color filter array 120F includes Quad Bayer color filter array. The color filter array 120F corresponds to 4×4 cells. The 4×4 cells include a plurality of first color cells FG6, a plurality of second color cells FR6, and a plurality of third color cells FB6.

In one embodiment, the second-type lens corresponds to a 2×2 lens CL61. One of the plurality of first color cells FG6 corresponds to a 1×1 cell. The second-type lens is arranged on the plurality of first color cells FG6.

In one embodiment, the first-type lens includes a first 1×1 lens CL62. One of the plurality of second color cells FR6 corresponds to a 1×1 cell. The first 1×1 lens CL62 is arranged on the one of the plurality of second color cells FR6.

In one embodiment, the second-type lens further includes a second 1×1 lens CL63. One of the plurality of third color cells FB6 corresponds to the 1×1 cell. The second 1×1 lens CL63 is arranged on the one of the plurality of third color cells FB6.

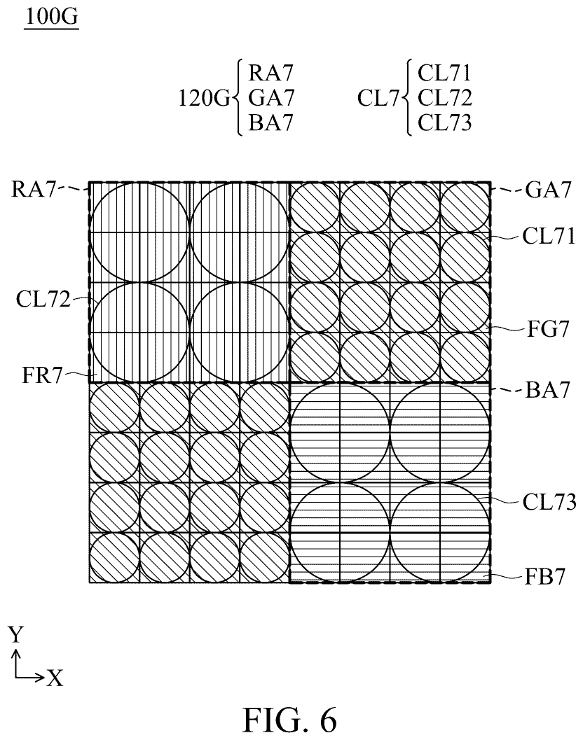

FIG. 6 is a top view schematic of an image sensing device according to one embodiment of the present disclosure. As shown in FIG. 6, in one embodiment, the image sensing device 100G includes a color filter array 120G and a plurality of lenses CL7. The color filter array 120G may include a plurality of first color areas GA7, a second color area RA7, and a third color area BA7. The first color area GA7 may include the plurality of first color cells FG7. The second color area RA7 may include the plurality of second color cells FR7. The third color area BA7 may include the plurality of third color cells FB7. The plurality of lenses CL7 may include the first-type lens CL71 and the second-type lens CL72 and CL73.

For example, the image sensing device 100G, the color filter array 120G, and the plurality of lenses CL7 of FIG. 6 may correspond to the image sensing device 100, the color filter array 120, and the plurality of lenses 130 of FIG. 1, but the present disclosure is not limited thereto.

In some embodiments, the color filter array 120G, the plurality of first color cells FG7, the plurality of second color cells FR7, and the plurality of third color cells FB7 of FIG. 6 may correspond to the color filter array 120A, the plurality of green color filters FG1, the plurality of red color filters FR1, and the plurality of blue color filters FB1 of FIG. 2A, but the present disclosure is not limited thereto.

In some embodiments, the first-type lens CL71 of FIG. 6 may correspond to one of the plurality of lenses CL1 of FIG. 2A, the second-type lens CL72 and CL73 of FIG. 6 may correspond to one of the plurality of lenses CL2 of FIG. 3A, but the present disclosure is not limited thereto.

In some embodiments, the color filter array 120G may have two first color areas GA7, one second color area RA7, and one third color area BA7, but the present disclosure is not limited thereto. In some embodiments, two first color areas GA7 may have thirty-two first color cells FG7, one second color area RA7 may have sixteen second color cells FR7, and one third color area BA7 may have sixteen third color cells FB7, but the present disclosure is not limited thereto.

In some embodiments, thirty-two first-type lens CL71 may be arranged on the thirty-two first color cells FG7, four second-type lens CL72 may be arranged on sixteen second color cells FR7, four second-type lens CL73 may be arranged on sixteen third color cells FB7, but the present disclosure is not limited thereto.

In some embodiments, one first color area GA7 may correspond to the 4×4 cell, one second color area RA7 may correspond to the 4×4 cell, and one third color area BA7 may correspond to the 4×4 cell, but the present disclosure is not limited thereto.

In some embodiments, one first color cell FG7 may correspond to the 1×1 cell, one second color cell FR7 may correspond to the 1×1 cell, and one third color cell FB7 may correspond to the 1×1 cell, but the present disclosure is not limited thereto.

In some embodiments, one first-type lens CL71 may correspond to the 1×1 cell, the second-type lens CL72 or CL73 may correspond to the 2×2 cell, but the present disclosure is not limited thereto.

In some embodiments, 1×1 OCL may be arranged on green pixel, 2×2 OCL may be arranged on red pixel, 2×2 OCL may be arranged on blue pixel. Therefore, the image sensing device 100E may exhibit improved PDAF performance in the red and blue channels and better image quality in the green channel.

For example, 1×1 OCL may correspond to the first-type lens CL71, 2×2 OCL may correspond to the second-type lens CL72 or CL73, the green pixel may correspond to the plurality of first color areas GA7, the red pixel may correspond to the second color area RA7, and the blue pixel may correspond to the third color area BA7, but the present disclosure is not limited thereto.

In some embodiments, the image sensing device 100G may have better PDAF performance and better image quality, but the present disclosure is not limited thereto.

Please refer to FIG. 1 and FIG. 6, in one embodiment, the color filter array 120 and 120G corresponds to 8×8 cells. The 8×8 cells include a plurality of first color cells FG7, a plurality of second color cells FR7, and a plurality of third color cells FB7.

In one embodiment, the first-type lens corresponds to a 1×1 lens CL71. The second-type lens includes a first 2×2 lens CL72 and a second 2×2 lens CL73. Each one of the plurality of first color cells FG7, the plurality of second color cells FR7, and the plurality of third color cells FB7 corresponds to a 1×1 cell. The first-type lens is arranged on the one of the plurality of first color cells FG7. The first 2×2 lens CL72 is arranged on the plurality of second color cells FR7. The second 2×2 lens CL73 is arranged on the plurality of third color cells FB7.

In some embodiment, the color filter array 120 and 120G further includes a first color area GA7. The plurality of lenses 130 and CL7 includes a first lens CL71. The first lens CL71 is arranged on the first color area GA7. The first lens CL71 corresponds to the first-type lens.

In some embodiment, the color filter array 120 and 120G includes a second color area RA7. The plurality of lenses 130 and CL7 includes a second lens CL72. The second lens CL72 is arranged on the second color area RA7. The second lens CL72 corresponds to the second-type lens. The second color area RA7 does not overlap by the first color area GA7.

In some embodiment, the color filter array 120 and 120G further includes a third color area FB7. The plurality of lenses includes a third lens CL73. The third lens CL73 is arranged on the third color area FB7. The third lens CL73 corresponds to the second-type lens. The first color area GA7, the second color area RA7, and the third color area BA7 are different from each other.

In some embodiment, the color filter array 120 and 120G includes hexadeca-cell, which may also be referred to as a 16-cell CFA. The color filter array corresponds to 8×8 cells. The 8×8 cells include a plurality of first color cells FG7, a plurality of second color cells FR7, and a plurality of third color cells FB7.

In some embodiment, the first-type lens corresponds to 1×1 lens CL71. Each one of the plurality of first color cells FG7 corresponds to 1×1 cell. The first-type lens is arranged on the one of the plurality of first color cells FG7.

In some embodiment, the second-type lens includes a first 2×2 lens CL72. Each one of the plurality of second color cells FR7 corresponds to 1×1 cell. The first 2×2 lens CL72 may be arranged on four second color cells FR7.

In some embodiment, the second-type lens further includes a second 2×2 lens CL73. One of the plurality of third color cells FB7 corresponds to the 1×1 cell. The second 2×2 lens CL73 may be arranged on four third color cells FB7.

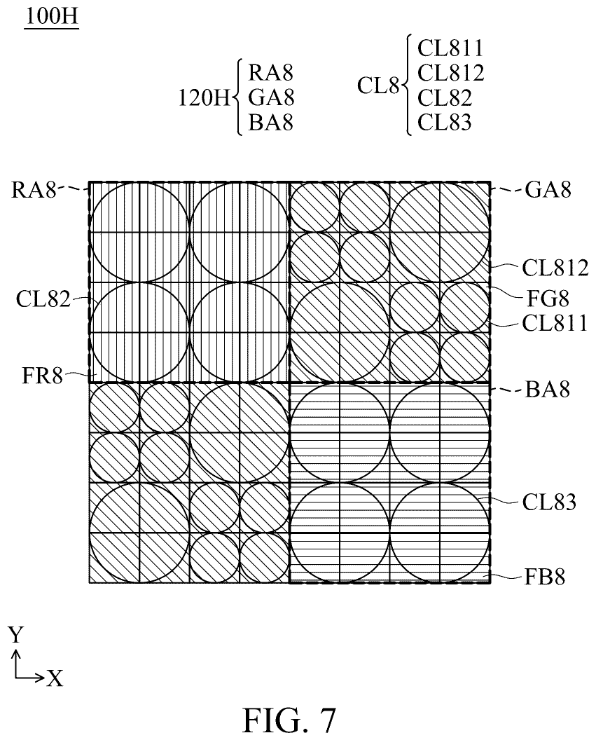

FIG. 7 is a top view schematic of an image sensing device according to one embodiment of the present disclosure. As shown in FIG. 7, in one embodiment, the image sensing device 100H includes a color filter array 120H and a plurality of lenses CL8. The color filter array 120H may include a plurality of first color areas GA8, the second color area RA8, and the third color area BA8. The first color area GA8 may include the plurality of first color cells FG8. The second color area RA8 may include the plurality of second color cells FR8. The third color area BA8 may include the plurality of third color cells FB8. The plurality of lenses CL8 may include the first-type lens CL811 and the plurality of second-type lenses CL812, CL82, and CL83.

For example, the image sensing device 100H, the color filter array 120H, and the plurality of lenses CL8 of FIG. 7 may correspond to the image sensing device 100, the color filter array 120, and the plurality of lenses 130 of FIG. 1, but the present disclosure is not limited thereto.

In some embodiments, the color filter array 120H, the plurality of first color cells FG8, the plurality of second color cells FR8, and the plurality of third color cells FB8 of FIG. 7 may correspond to the color filter array 120A, the plurality of green color filters FG1, the plurality of red color filters FR1, and the plurality of blue color filters FB1 of FIG. 2A, but the present disclosure is not limited thereto.

In some embodiments, the first-type lens CL811 of FIG. 7 may correspond to one of the plurality of lenses CL1 of FIG. 2A, and the plurality of second-type lenses CL812, CL82, and CL83 of FIG. 7 may correspond to one of the plurality of lenses CL2 of FIG. 3A, but the present disclosure is not limited thereto.

In some embodiments, the color filter array 120H may have two first color areas GA8, one second color area RA8, and one third color area BA8, but the present disclosure is not limited thereto. In some embodiments, two first color areas GA8 may have thirty-two first color cells FG8, one second color area RA8 may have sixteen second color cells FR8, and one third color area BA8 may have sixteen third color cells FB8, but the present disclosure is not limited thereto.

In some embodiments, sixteen first-type lens CL811 may be arranged on the sixteen first color cells FG8, four second-type lens CL812 may be arranged on sixteen first color cells FG8, four second-type lens CL82 may be arranged on sixteen second color cells FR8, four second-type lens CL83 may be arranged on sixteen third color cells FB8, but the present disclosure is not limited thereto.

In some embodiments, one first color area GA8 may correspond to the 4×4 cell, one second color area RA8 may correspond to the 4×4 cell, and one third color area BA8 may correspond to the 4×4 cell, but the present disclosure is not limited thereto.

In some embodiments, one first color cell FG8 may correspond to the 1×1 cell, one second color cell FR8 may correspond to the 1×1 cell, and one third color cell FB8 may correspond to the 1×1 cell, but the present disclosure is not limited thereto.

In some embodiments, one first-type lens CL811 may correspond to the 1×1 cell, the second-type lens CL812, CL82, or CL83 may correspond to the 2×2 cell, but the present disclosure is not limited thereto.

In some embodiments, 1×1 OCL and 2×2 OCL may be mix arranged on green pixel, 2×2 OCL may be arranged on red pixel, 2×2 OCL may be arranged on blue pixel. Therefore, the image sensing device 100H may exhibit improved PDAF performance in the red, blue and green channels, and also have better image quality in the green channel.

For example, 1×1 OCL may correspond to the first-type lens CL811, 2×2 OCL may correspond to the second-type lens CL812, CL82, or CL83, the green pixel may correspond to the plurality of first color areas GA8, the red pixel may correspond to the second color area RA8, and the blue pixel may correspond to the third color area BA8, but the present disclosure is not limited thereto.

In some embodiments, the image sensing device 100H may have better PDAF performance and better image quality, but the present disclosure is not limited thereto.

Please refer to FIG. 1 and FIG. 7, in one embodiment, the first-type lens includes a first 1×1 lens CL811. The second-type lens includes a first 2×2 lens CL812. Each one of the plurality of first color cells FG8 correspond to a 1×1 cell. The first 1×1 lens CL811 is arranged on one of the plurality of first color cell FG8. The first 2×2 lens CL812 may be arranged on a part of the plurality of (or four of) the first color cells FG8.

In one embodiment, the second-type lens further includes a second 2×2 lens CL82 and a third 2×2 lens CL83. Each one of the plurality of second color cells FR8 and the plurality of third color cells FB8 corresponds to the 1×1 cell. The second 2×2 lens CL82 may be arranged on a part of the plurality of (or four of) the second color cells FR8. The third 2×2 lens CL83 may be arranged on a part of the plurality of (or four of) the third color cells FB8.

In some embodiment, the color filter array 120 and 120H includes the first color area GA8. The plurality of lenses 130 and CL8 includes a first lens CL812. The first lens CL812 is arranged on the first color area GA8. The first lens CL812 corresponds to the second-type lens.

In some embodiment, the color filter array 120H further includes the second color area RA8. The plurality of lenses further includes a second lens CL82. The second lens CL82 is arranged on the second color area RA8. The second lens CL82 corresponds to the first-type lens. The second color area RA8 does not overlap by the first color area GA8.

In some embodiment, the color filter array 120H further includes a third color area BA8. The plurality of lenses further includes a third lens CL83. The third lens CL83 is arranged on the third color area BA8. The third lens CL83 corresponds to the first-type lens. The first color area GA8, the second color area RA8, and the third color area BA8 are different from each other.

In some embodiment, the color filter array 120H includes hexadeca-cell, which may also be referred to as a 16-cell CFA. The color filter array 120H corresponds to 8×8 cells. The 8×8 cells include a plurality of first color cells FG8, a plurality of second color cells FR8, and a plurality of third color cells FB8.

In some embodiment, the second-type lens corresponds to 2×2 lens CL812. Each one of the plurality of first color cells FG8 corresponds to 1×1 cell. The second-type lens is arranged on four of the plurality of first color cells FG8.

In some embodiment, the first-type lens includes a first 1×1 lens CL82. Each one of the plurality of second color cells FR8 corresponds to 1×1 cell. The first 1×1 lens CL82 is arranged on the one of the plurality of second color cells FR8.

In some embodiment, the one type lens further includes a second 2×2 lens CL83. One of the plurality of third color cells FB8 corresponds to the 1×1 cell. The second 2×2 lens CL83 is arranged on four of the plurality of third color cells FB8.

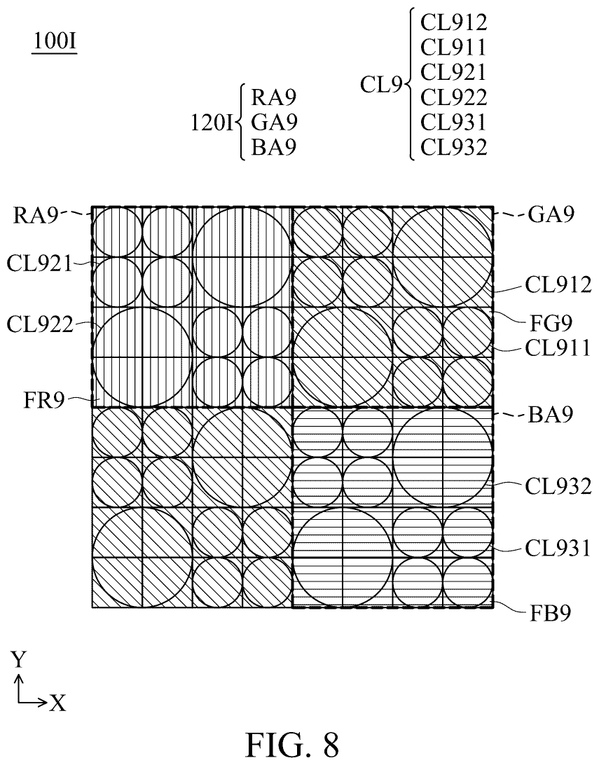

FIG. 8 is a top view schematic of an image sensing device according to one embodiment of the present disclosure. As shown in FIG. 8, in one embodiment, the image sensing device 100I includes a color filter array 120I and a plurality of lenses CL9. The color filter array 120I may include a plurality of first color areas GA9, a second color area RA9, and a third color area BA9. The first color area GA9 may include the plurality of first color cells FG9. The second color area RA9 may include the plurality of second color cells FR9. The third color area BA9 may include the plurality of third color cells FB9. The plurality of lenses CL9 may include a plurality of first-type lenses CL911, CL921, and CL931 and a plurality of second-type lenses CL912, CL922, and CL932.

For example, the image sensing device 100I, the color filter array 120I, and the plurality of lenses CL9 of FIG. 8 may correspond to the image sensing device 100, the color filter array 120, and the plurality of lenses 130 of FIG. 1, but the present disclosure is not limited thereto.

In some embodiments, the color filter array 120I, the plurality of first color cells FG9, the plurality of second color cells FR9, and the plurality of third color cells FB9 of FIG. 8 may correspond to the color filter array 120A, the plurality of green color filters FG1, the plurality of red color filters FR1, and the plurality of blue color filters FB1 of FIG. 2A, but the present disclosure is not limited thereto.

In some embodiments, the plurality of first-type lenses CL911, CL921, and CL931 of FIG. 8 may correspond to one of the plurality of lenses CL1 of FIG. 2A, and the plurality of second-type lenses CL912, CL922, and CL932 of FIG. 8 may correspond to one of the plurality of lenses CL2 of FIG. 3A, but the present disclosure is not limited thereto.

In some embodiments, the color filter array 120I may have two first color areas GA9, one second color area RA9, and one third color area BA9, but the present disclosure is not limited thereto. In some embodiments, two first color areas GA9 may have thirty-two first color cells FG9, one second color area RA9 may have sixteen second color cells FR9, and one third color area BA9 may have sixteen third color cells FB9, but the present disclosure is not limited thereto.

In some embodiments, sixteen first-type lens CL911 may be arranged on the sixteen first color cells FG9, four second-type lens CL912 may be arranged on sixteen first color cells FG9, eight first-type lens CL921 may be arranged on the eight second color cells FR9, two second-type lens CL922 may be arranged on eight second color cells FR9, eight first-type lens CL931 may be arranged on the eight third color cells FB9, two second-type lens CL932 may be arranged on eight third color cells FB9, but the present disclosure is not limited thereto.

In some embodiments, one first color area GA9 may correspond to the 4×4 cell, one second color area RA9 may correspond to the 4×4 cell, and one third color area BA9 may correspond to the 4×4 cell, but the present disclosure is not limited thereto.

In some embodiments, one first color cell FG9 may correspond to the 1×1 cell, one second color cell FR9 may correspond to the 1×1 cell, and one third color cell FB9 may correspond to the 1×1 cell, but the present disclosure is not limited thereto.

In some embodiments, one first-type lens CL911, CL921, or CL931 may correspond to the 1×1 cell, the second-type lens CL912, CL922, or CL932 may correspond to the 2×2 cell, but the present disclosure is not limited thereto.

In some embodiments, 1×1 OCL and 2×2 OCL may be mix arranged on green pixel, 1×1 OCL and 2×2 OCL may be mix arranged on red pixel, 1×1 OCL and 2×2 OCL may be mix arranged on blue pixel. Therefore, the image sensing device 100I may exhibit improved PDAF performance and better image quality in all channels.

For example, 1×1 OCL may correspond to the first-type lens CL911, CL921, or CL931, 2×2 OCL may correspond to the second-type lens CL912, CL922, or CL932, the green pixel may correspond to the plurality of first color areas GA9, the red pixel may correspond to the second color area RA9, and the blue pixel may correspond to the third color area BA9, but the present disclosure is not limited thereto.

In some embodiments, the image sensing device 100I may have better PDAF performance and better image quality, but the present disclosure is not limited thereto.

Please refer to FIG. 1 and FIG. 8, in one embodiment, the first-type lens includes a first 1×1 lens CL911. The second-type lens includes a first 2×2 lens CL912. Each one of the plurality of first color cells FG9 corresponds to a 1×1 cell. The first 1×1 lens CL 911 is arranged on one of the plurality of first color cells FG9. The first 2×2 lens CL912 is arranged on a part of the plurality of (or four of) the first color cells FG9.

In one embodiment, the first-type lens includes a second 1×1 lens CL921 and a third 1×1 lens CL931. Each one of the plurality of second color cells FR9 corresponds to the 1×1 cell. Each one of plurality of third color cells FB9 corresponds to the 1×1 cell. The second 1×1 lens CL921 is arranged on one of the plurality of second color cells FR9. The third 1×1 lens CL931 is arranged on one of the plurality of third color cells FB9.

In one embodiment, the second-type lens further includes a second 2×2 lens CL922 and a third 2×2 lens CL932. The second 2×2 lens CL922 is arranged on a part of the plurality of (or four of) the second color cells FR9. The third 2×2 lens CL932 is arranged on a part of the plurality of (or four of) the third color cells FB9.

In some embodiment, the color filter array 120 and 120I further includes a first color area GA9. The plurality of lenses 130 and CL9 includes a first lens CL911. The first lens CL911 is arranged on the first color area GA9. The first lens CL911 corresponds to the first-type lens.

In some embodiment, the color filter array 120 and 120I includes a second color area RA9. The plurality of lenses 130 and CL9 includes a second lens CL922. The second lens CL922 is arranged on the second color area RA9. The second lens CL922 corresponds to the second-type lens. The second color area RA9 does not overlap by the first color area GA9.

In some embodiment, the color filter array 120 and 120I further includes a third color area FB9. The plurality of lenses includes a third lens CL932. The third lens CL932 is arranged on the third color area FB9.The third lens CL932 corresponds to the second-type lens. The first color area GA9, the second color area RA9, and the third color area BA9 are different from each other.

In some embodiment, the color filter array 120 and 120I includes hexadeca-cell, which may also be referred to as a 16-cell CFA. The color filter array corresponds to 8×8 cells. The 8×8 cells include a plurality of first color cells FG9, a plurality of second color cells FR9, and a plurality of third color cells FB9.

In some embodiment, the first-type lens corresponds to 1×1 lens CL911. Each one of the plurality of first color cells FG9 corresponds to 1×1 cell. The first-type lens is arranged on the one of the plurality of first color cells FG9.

In some embodiment, the second-type lens includes a first 2×2 lens CL922. Each one of the plurality of second color cells FR9 corresponds to 1×1 cell. The first 2×2 lens CL922 is arranged on four of second color cells FR9.

In some embodiment, the second-type lens further includes a second 2×2 lens CL932. One of the plurality of third color cells FB9 corresponds to the 1×1 cell. The second 2×2 lens CL932 is arranged on four of third color cells FB9.

In some embodiment, the color filter array 120 and 120I includes the first color area GA9. The plurality of lenses 130 and CL9 includes a first lens CL912. The first lens CL912 is arranged on the first color area GA9. The first lens CL912 corresponds to the second-type lens.

In some embodiment, the color filter array 120I further includes the second color area RA9. The plurality of lenses further includes a second lens CL921. The second lens CL921 is arranged on the second color area RA9. The second lens CL921 corresponds to the first-type lens. The second color area RA9 does not overlap by the first color area GA9.

In some embodiment, the color filter array 120I further includes a third color area BA9. The plurality of lenses further includes a third lens CL93. The third lens CL93 is arranged on the third color area BA9. The third lens CL93 corresponds to the first-type lens. The first color area GA9, the second color area RA9, and the third color area BA9 are different from each other.

In some embodiment, the color filter array 120I includes hexadeca-cell filter array. The color filter array 120I corresponds to 8×8 cells. The 8×8 cells include a plurality of first color cells FG9, a plurality of second color cells FR9, and a plurality of third color cells FB9.

In some embodiment, the second-type lens corresponds to 2×2 lens CL912. Each one of the plurality of first color cells FG9 corresponds to 1×1 cell. The second-type lens is arranged on the plurality of first color cells FG9.

In some embodiment, the first-type lens includes a first 1×1 lens CL921. Each one of the plurality of second color cells FR9 corresponds to 1×1 cell. The first 1×1 lens CL921 is arranged on one of the plurality of second color cells FR9.

In some embodiment, the second-type lens further includes a second 1×1 lens CL931. One of the plurality of third color cells FB9 corresponds to the 1×1 cell. The second 1×1 lens CL931 is arranged on the one of the plurality of third color cells FB9.

In some embodiments, the image sensing device 100 that uses a Quad Bayer color filter array (4-cell CFA) may include any combination of at least one image sensing device 100E and/or at least one image sensing device 100F. Alternatively, the image sensing device 100 that includes hexadeca-cell color filter array (16-cell CFA) may include any combination of image sensing devices 100G, 100H, and/or 100I.

Therefore, according to the technical content of the present disclosure, the image sensing device shown in the embodiment of the present disclosure can achieve the effect of combining high resolution with excellent autofocus performance. Furthermore, the image sensing device 100E, 100F, 100G, 100H, or 100I shown in the embodiment may have better PDAF performance and better image quality.

It should also be understood that ordinal terms such as “first” and “second” used in the specification and the claims are merely for distinguishing between similar elements, and do not imply any temporal or sequential order, nor do they indicate any order of manufacturing or arrangement between the elements. The use of such ordinals is intended solely to clarify the distinction between elements of similar designation. The terminology used in the claims may differ from that in the specification; for example, an element referred to as the “first element” in the specification may be referred to as the “second element” in the claims.

The scope of protection described in this disclosure is not limited to the processes, machines, manufacture, compositions of matter, devices, methods, or steps of the specific embodiments described in the specification. Any person of ordinary skill in the art can understand from the disclosure that any currently known or future-developed processes, machines, manufacture, compositions of matter, devices, methods, or steps that perform substantially the same function or achieve substantially the same result as those in the disclosed embodiments may be utilized in accordance with this disclosure. Therefore, the scope of protection of this disclosure includes such processes, machines, manufacture, compositions of matter, devices, methods, and steps. Any embodiment or claim of this disclosure need not achieve all of the objectives, advantages, and/or features disclosed herein.

Several embodiments have been outlined above to facilitate the understanding of the disclosed embodiments by those skilled in the art. It should be understood by those skilled in the art that they may design or modify other processes and structures based on the disclosed embodiments to achieve the same objectives and/or advantages as those described herein. It should also be understood by those skilled in the art that such equivalent processes and structures do not depart from the spirit and scope of the present disclosure, and that various modifications, substitutions, and alterations may be made without departing from the spirit and scope of the present disclosure.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A image sensing device, comprising:
a plurality of photoelectric converters;
a color filter array, configured to be arranged on the plurality of photoelectric converters;
a plurality of lenses, configured to be arranged on the color filter array;
wherein the plurality of lenses comprises a first-type lens and a second-type lens;
wherein a second size of the second-type lens is greater than a first size of the first-type lens.

2. The image sensing device as claimed in claim 1, wherein
the color filter array comprises a first color area;
wherein the plurality of lenses comprises a first lens;
wherein the first lens is arranged on the first color area;
wherein the first lens corresponds to the first-type lens.

3. The image sensing device as claimed in claim 2, wherein
the color filter array further comprises a second color area;
wherein the plurality of lenses further comprises a second lens;
wherein the second lens is arranged on the second color area;
wherein the second lens corresponds to the second-type lens;
wherein the second color area does not overlap by the first color area.

4. The image sensing device as claimed in claim 3, wherein
the color filter array further comprises a third color area;
wherein the plurality of lenses further comprises a third lens;
wherein the third lens is arranged on the third color area;
wherein the third lens corresponds to the second-type lens;
wherein the first color area, the second color area, and the third color area are different from each other.

5. The image sensing device as claimed in claim 1, wherein
the color filter array comprises a first color area;
wherein the plurality of lenses comprises a first lens;
wherein the first lens is arranged on the first color area;
wherein the first lens corresponds to the second-type lens.

6. The image sensing device as claimed in claim 5, wherein
the color filter array further comprises a second color area;
wherein the plurality of lenses further comprises a second lens;
wherein the second lens is arranged on the second color area;
wherein the second lens corresponds to the first-type lens;
wherein the second color area does not overlap by the first color area.

7. The image sensing device as claimed in claim 6, wherein
the color filter array further comprises a third color area;
wherein the plurality of lenses further comprises a third lens;
wherein the third lens is arranged on the third color area;
wherein the third lens corresponds to the first-type lens;
wherein the first color area, the second color area, and the third color area are different from each other.

8. The image sensing device as claimed in claim 1, wherein
the color filter array comprises quad bayer color filter array;
wherein the color filter array corresponds to 4×4 cells;
wherein the 4×4 cells comprise a plurality of first color cells, a plurality of second color cells, and a plurality of third color cells.

9. The image sensing device as claimed in claim 8, wherein
the first-type lens corresponds to a 1×1 lens;
wherein each one of the plurality of first color cells corresponds to a 1×1 cell;
wherein the first-type lens is arranged on one of the plurality of first color cells.

10. The image sensing device as claimed in claim 9, wherein
the second-type lens comprises a first 2×2 lens;
wherein each one of the plurality of second color cells corresponds to a 1×1 cell;
wherein the first 2×2 lens is arranged on the plurality of second color cells.

11. The image sensing device as claimed in claim 10, wherein
the second-type lens further comprises a second 2×2 lens;
wherein each one of the plurality of third color cells corresponds to the 1×1 cell;
wherein the second 2×2 lens is arranged on the plurality of third color cells.

12. The image sensing device as claimed in claim 8, wherein
the second-type lens corresponds to a 2×2 lens;
wherein each one of the plurality of first color cells corresponds to a 1×1 cell;
wherein the second-type lens is arranged on the plurality of first color cells.

13. The image sensing device as claimed in claim 12, wherein
the first-type lens comprises a first 1×1 lens;
wherein each one of the plurality of second color cells corresponds to a 1×1 cell;
wherein the first 1×1 lens is arranged on one of the plurality of second color cells.

14. The image sensing device as claimed in claim 13, wherein
the second-type lens further comprises a second 1×1 lens;
wherein each one of the plurality of third color cells corresponds to the 1×1 cell;
wherein the second 1×1 lens is arranged on one of the plurality of third color cells.

15. The image sensing device as claimed in claim 1, wherein
the color filter array corresponds to 8×8 cells;
wherein the 8×8 cells comprise a plurality of first color cells, a plurality of second color cells, and a plurality of third color cells.

16. The image sensing device as claimed in claim 15, wherein
the first-type lens corresponds to a 1×1 lens;
the second-type lens comprises a first 2×2 lens and a second 2×2 lens;
wherein each one of the plurality of first color cells, each one of the plurality of second color cells, and each one of the plurality of third color cells correspond to 1×1 cell;
wherein the first-type lens is arranged on one of the plurality of first color cells;
wherein the first 2×2 lens is arranged on four of the plurality of second color cells;
wherein the second 2×2 lens is arranged on four of the plurality of third color cells.

17. The image sensing device as claimed in claim 15, wherein
the first-type lens comprises a first 1×1 lens;
wherein the second-type lens comprises a first 2×2 lens;
wherein each one of the plurality of first color cells correspond to a 1×1 cell;
wherein the first 1×1 lens is arranged on one of the plurality of first color cells;
wherein the first 2×2 lens is arranged on four of the plurality of first color cells.

18. The image sensing device as claimed in claim 17, wherein
the second-type lens further comprises a second 2×2 lens and a third 2×2 lens;
wherein each one of the plurality of second color cells and the plurality of third color cells correspond to the 1×1 cell;
wherein the second 2×2 lens is arranged on four of the plurality of second color cells;
wherein the third 2×2 lens is arranged on four of the plurality of third color cells.

19. The image sensing device as claimed in claim 17, wherein
the first-type lens comprises a second 1×1 lens and a third 1×1 lens;
wherein each one of the plurality of second color cells corresponds to the 1×1 cell;
wherein each one of the plurality of third color cells corresponds to the 1×1 cell;
wherein the second 1×1 lens is arranged on one of the plurality of second color cells;
wherein the third 1×1 lens is arranged on one of the plurality of third color cells.

20. The image sensing device as claimed in claim 19, wherein
the second-type lens further comprises a second 2×2 lens and a third 2×2 lens;
wherein the second 2×2 lens is arranged on four of the plurality of second color cells;
wherein the third 2×2 lens is arranged on four of the plurality of third color cells.
